(19) United States
(12) Patent Application Publication
(10) Pub. No.: US 2008/0203512 A1
(43) Pub. Date: Aug. 28, 2008

(54) Image sensor chip package

(75) Inventors: Steven Webster, Tu-Cheng (TW); Ying-Cheng Wu, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: Hon Hai Precision Industry Co., LTD.

(21) Appl. No.: 12/151,369

(22) Filed: May 6, 2008

Related U.S. Application Data
(63) Continuation-in-part of application No. 11/448,314, filed on Jun. 7, 2006.

(51) Int. Cl. H01L 31/0203

(52) U.S. Cl. 257/434; 257/E31.11

(57) ABSTRACT

A chip package includes a carrier (32), an image sensor chip (34), a plurality of wires (36), an adhesive means (3262) and a transparent cover (38). The carrier has a cavity (321) therein. The image sensor chip is received in the cavity, and the image sensor has a photosensitive area (344). Each wire electronically connects the image sensor chip and the carrier. The adhesive means is applied to the image sensor chip around the photosensitive area and covers at least one portion of all the wires adjacent to the photosensitive area. The adhesive means surrounds an enclosing body (3264) around the photosensitive area. The transparent cover is mounted to the carrier, and the cover is adhered to the carrier with the adhesive means. The cover with the enclosing body defines a sealing space (37) for enclosing the photosensitive area of the image sensor chip therein.

### CROSS-REFERENCE TO RELATED APPLICATION

This application is a continuation-in-part application of U.S. application Ser. No. 11/448,314, filed on Jun. 7, 2006.

### BACKGROUND OF THE INVENTION

1. Field of the Invention

The present invention generally relates to an integrated circuit (IC) chip package and, particularly, to a digital camera module with an image sensor chip package.

2. Description of Related Art

Image sensors are widely used in digital camera modules in order to convert the optical image data of an object into electrical signals. In order to protect the image sensor from contamination or pollution (i.e. from dust or water vapor), the image sensor is generally sealed in a structural package.

A typical image sensor chip package (not labeled) is illustrated in FIG. 10. The image sensor chip package is constructed to include a plurality of conductors 130, a base 146, a chip 152 and a cover 158. The base 146 includes a bottom portion 148 and four sidewalls 149. The bottom portion 148 and the sidewalls 149 cooperatively form a space 150. Each conductor 130 includes a first conductive portion 140, a second conductive portion 142 and a third conductive portion 144. The first and second conductive portions 140, 142 are respectively mounted on two sides of the bottom portion 148. The third conductive portion 144 runs through the bottom portion 148 so as to connect the first and second conductive portions 140, 142. The chip 152 includes a number of pads 154 formed thereon. The chip 152 is received in the space 150 and fixed on the base 146 by an adhesive glue 160. A number of bonding wires 156 are provided to connect the pads 154 and the first conductive portion 140 of the conductors 130. The cover 158 is transparent and secured to the top of the sidewalls 149 via an adhesive glue 162, thereby hermetically sealing the space 150 and allowing light beams to pass therethrough.

In the process of forming the conductors 130, a number of interconnection holes 166 are defined in the base 146. The first portions 140 and the second portions 142 are formed by means of plating metal. The third portions 136 are formed by filling molten metal into the interconnection holes 166 and then allowing it to solidify. Accordingly, the first portion 140, the second portion 142 and the third portion 136 are electronically connected with each other. It is obvious that this method of forming the conductors 130 is complex and as a result it is also expensive. Furthermore, after the conductors 130 are formed, water vapor can enter the space 150 via the interconnection holes 166. Thus, the chip 152 may be polluted and the conductors 130 may be damaged.

In addition, the relative large volume of the image sensor chip package results in more dust-particles adhering to the cover 158, the bottom board 1462 and the sidewalls 1464 of the base 146. Thus, more dust-particles will drop onto the chip 152. The dust-particles obscure the optical path and produce errors in the image sensing process. Accordingly, the quality and/or reliability of the image sensor chip package 100 can be effected. Moreover, the bonding wires 156 exposed in the space 150 lack protection and may thus easily be damaged by dust-particles entering the space 150.

Therefore, a new image sensor chip package is desired in order to overcome the above-described shortcomings.

### SUMMARY OF THE INVENTION

One embodiment of a chip package includes a carrier, an image sensor chip, a plurality of wires, an adhesive means and a transparent cover. The carrier has a cavity therein. The image sensor chip is received in the cavity, and the image sensor has a photosensitive area. Each wire electronically connects the image sensor chip and the carrier. The adhesive means is applied to the image sensor chip around the photosensitive area and covers at least one portion of all the wires adjacent to the photosensitive area. The adhesive means forms an enclosing body around the photosensitive area. The transparent cover is mounted to the carrier, and the cover is adhered to the carrier with the adhesive means. The cover with the enclosing body surrounds a sealing space for enclosing the photosensitive area of the image sensor chip therein.

Other advantages and novel features will become more apparent from the following detailed description when taken in conjunction with the accompanying drawings.

### BRIEF DESCRIPTION OF THE DRAWINGS

Many aspects of the present image sensor chip package can be better understood with reference to the following drawings. The components in the drawings are not necessarily drawn to scale, the emphasis instead being placed upon clearly illustrating the principles of the image sensor chip package. Moreover, in the drawings, like reference numerals designate corresponding parts throughout the several views, in which:

FIG. 1 is a schematic, cross-sectional view of a digital camera module with an image sensor chip package according to a preferred embodiment;

FIG. 2 is a schematic, top plan view of the leadframe of FIG. 1;

FIG. 3 is a cross-sectional view of the leadframe in FIG. 2 along a line III-III;

FIG. 4 is a schematic, top view of the carrier shown in FIG. 1;

FIG. 5 is a schematic, bottom view of the carrier shown in FIG. 4;

FIG. 6 is a schematic, top view of the image sensor chip package without a cover;

FIG. 7 is a schematic, cross-sectional view of an image sensor chip package with a cover;

FIG. 8 is a schematic of the cover showing two areas of the cover to be adhered with adhesive glues;

FIG. 9 is a schematic, cross-sectional view of an image sensor chip package showing a range covering the adhesive glue according to another embodiment; and

FIG. 10 is a schematic, cross-sectional view of a typical image sensor chip package.

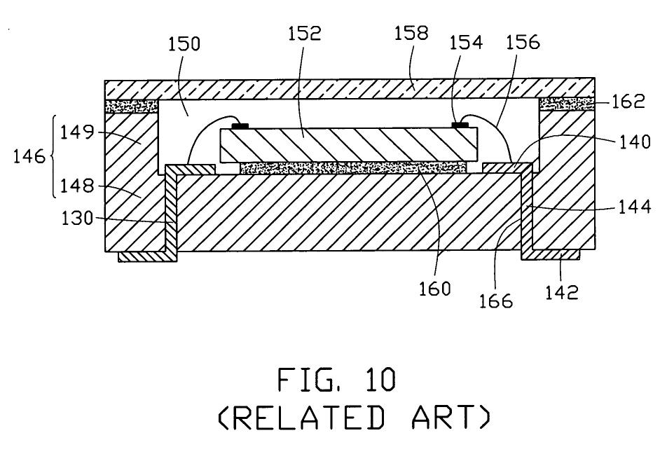

### DETAILED DESCRIPTION OF THE PERFERRED EMBODIMENTS

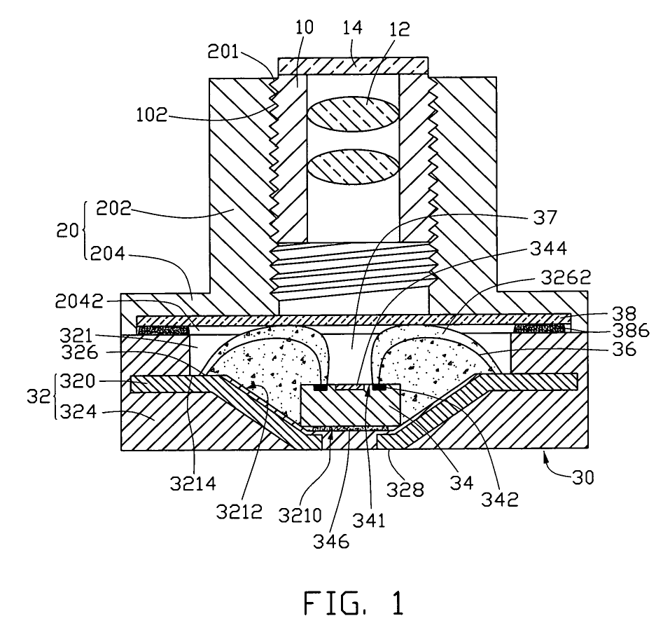

Referring to FIG. 1, a digital camera module includes a barrel 10, a seat 20 and an image sensor chip package 30 in accordance with a preferred embodiment. The barrel 10 and the seat 20 constitute a lens module. The image sensor chip package 30 includes a carrier 32, a cover 38, a chip 34, and a number of bonding wires 36.

The barrel 10 is substantially a hollow cylinder with two open ends so that light can be transmitted therethrough. Several lens elements 12 are disposed in the barrel 10, and receive incoming light that enters from the outside. The barrel 10 has an outer thread 102 defined in an outer periphery wall thereof. A glass board 14 is disposed before the lens elements 12 and covers one end of the barrel 10. As such, the glass board 14 protects the lens elements 12 from being scraped or otherwise abraded and keeps dust from entering the system.

The seat 20 includes a seat body 202 and a flange 204 formed together. The seat body 202 is a hollow cylinder. The flange 204 is formed at a bottom end of the seat body 202. The flange 204 has a rectangular cavity 2042 defined in a middle thereof opposite to the seat body 202. The rectangular cavity 2042 communicates with the seat body 202 so that light can be transmitted therethrough. An outer diameter of the seat body 202 is smaller than an edge of the flange 204 so that a step is formed at a connection between them. An inner periphery wall of the seat body 202 defines an inner thread 201, for engaging with the outer thread 102 of the barrel 10.

The carrier 32 of the image sensor chip package 30 includes a leadframe 320 and a plastic base 324. The leadframe 320 is embedded in the plastic base 324. The leadframe 320 and the plastic base 324 integrally form the carrier 32 by insert-molding. The carrier 32 has a receiving cavity 321 therein. The receiving cavity 321 has a bottom surface 3210, a slope surface 3212 and a support surface 3214. The support surface 3214 forms a plurality of upper pads 326 thereon spaced each other.

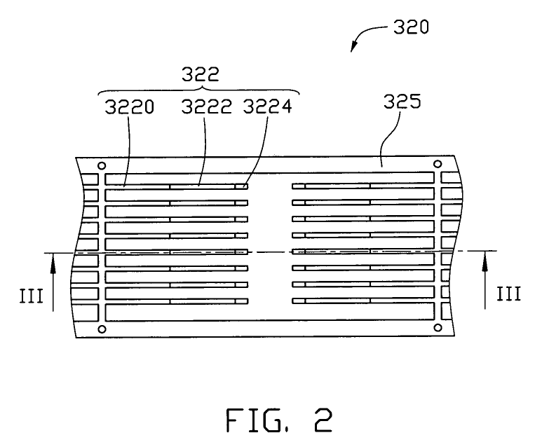

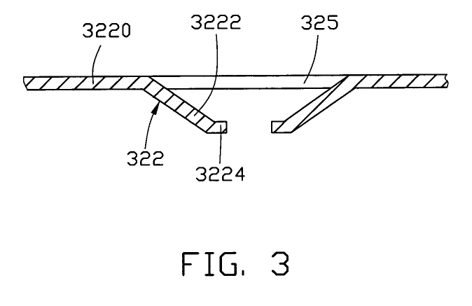

Referring to FIGS. 2 and 3, the leadframe 320 includes a number of conductive pieces 322 and a rectangular edge 325 made of metal. The conductive pieces 322 and the edge 325 are formed by either punching or etching on a sheet metal. The conductive pieces 322 are divided into two groups. The two groups are symmetrically arranged and are connected by the edge 325. The conductive pieces 322 in the same group are parallel to and spaced from each other. Each of the conductive pieces 322 includes a first terminal portion 3220, a second connecting portion 3222 and a third terminal portion 3224, the second connecting portion 3222 interconnecting the first and third terminal portions 3220, 3224. The first and third portions 3220, 3224 are spaced apart and aligned in parallel to each other. The second portion 3222 is slanted relative to the first and third portions 3220, 3224.

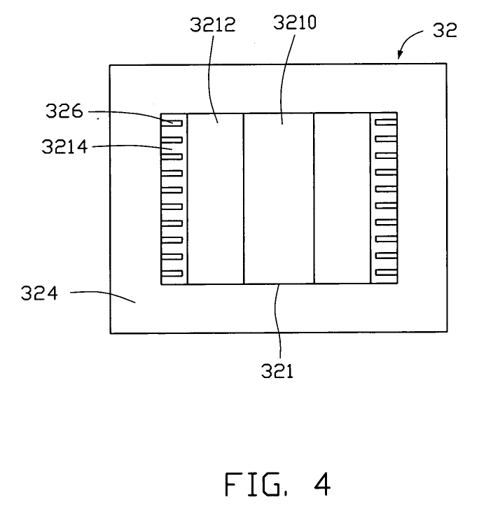

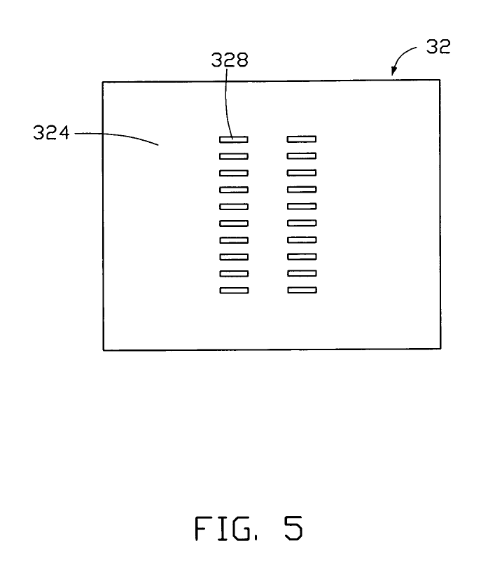

During insert-molding, the plastic base 324 partially encloses the upper and lower surfaces of the leadframe 320. After insert-molding, the leadframe 320 is cut along two sides. Referring to FIGS. 4 and 5, the carrier 32 defines a receiving cavity 321 therein. One part of each of the first portions 3220 is exposed on the support surface 3214, thus forming a plurality of upper pads 326. A distal end of each of the third portions 3224 is exposed on a bottom area of the carrier 32, thus forming a number of lower pads 328. The upper pads 326 are configured for electronically connecting to the image sensor chip 34. The lower pads 328 are configured for electronically connecting to a printing circuit board (PCB), thereby electronically connecting the leadframe 320 to the PCB so as to transmit electric signals out of the image sensor chip package 30. Referring to FIG. 1, the slope surface 3212 and the bottom surface 3210 cooperatively surround a trapezoidal space (not label) configured for receiving the image sensor chip 34.

The cover 38 is transparent and is configured for being laid over the image sensor chip 34 for light to transmitted therethrough. The cover 38 is configured for disposing on the carrier 32 so as to seal the receiving cavity 321.

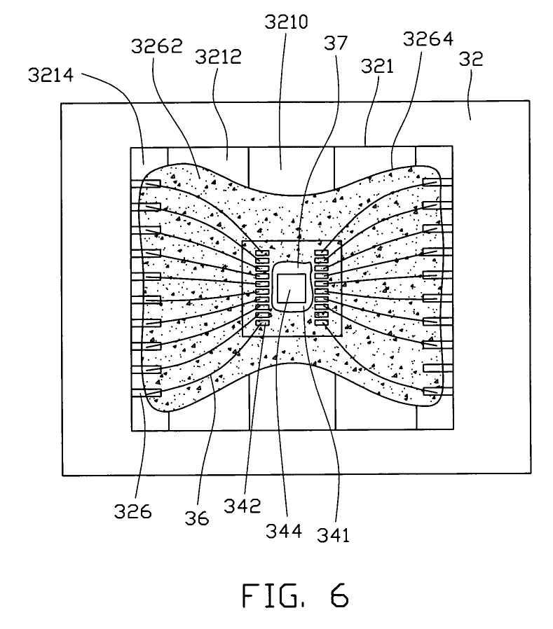

Referring to FIG. 6, the image sensor chip 34 is received in the trapezoidal space of the receiving cavity 321, and is adhered to the bottom surface 3210 of the carrier 32 via a double-sided adhesive tape 346. Alternatively, the double-sided adhesive tape 346 can be replaced by any other appropriate adhesive means. A top surface 341 of the image sensor chip 34 is arranged with a photosensitive area 344 and a number of chip pads 342 around the photosensitive area 344. The chip pads 342 are arranged on a left side and a right side of the photosensitive area 344.

The bonding wires 36 can be made of a conductive material such as gold or aluminum alloy. One end of each bonding wires 36 is connected/joined with a respective chip pad 342 of the image sensor chip 34, and the other end of the bonding wires 36 is connected/joined with a respective upper pad 326 forming by the first portions 3220 of the leadframe 320.

An adhesive glue 3262, such as a silicone, epoxy, acrylic, or polyamide adhesive, is applied to the top surface 341 of the image sensor chip 34 and around the image sensor chip 34. The adhesive glue 3262 not only covers the right side and the left side of the photosensitive area 344, but also covers an upper side and a lower side of the photosensitive area 344. The adhesive glue 3262 further covers the chip pads 342 and the bonding wires 36. In this embodiment, the adhesive glue 3262 also covers other areas around the image sensor chip 34. In addition, the adhesive glue 3262 covers both the upper pads 326 of the support surface 3214 and the slope surface 3212 of the receiving cavity 321. Portions of the enclosing body 3264 are filled in the trapezoidal space of the receiving cavity 321. Therefore, the adhesive glue 3262 surrounds the photosensitive area 344, thereby forming an enclosing body 3264 around the photosensitive area 344. The top view of the enclosing body 3264 shown herein for illustrative purpose is substantially rectangular, however, any other shapes such as square or irregular may also be used so long as the photosensitive area 344 is not covered.

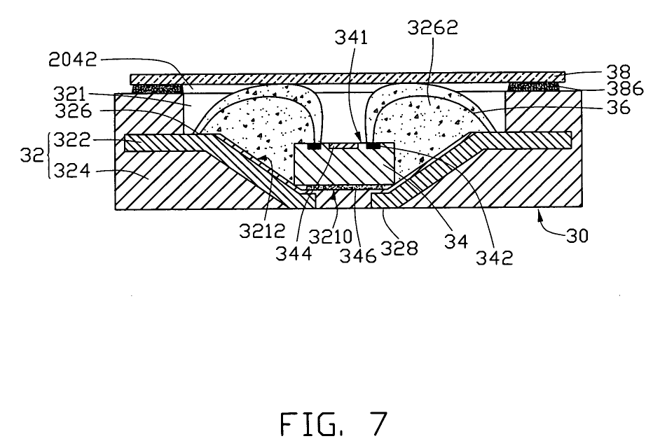

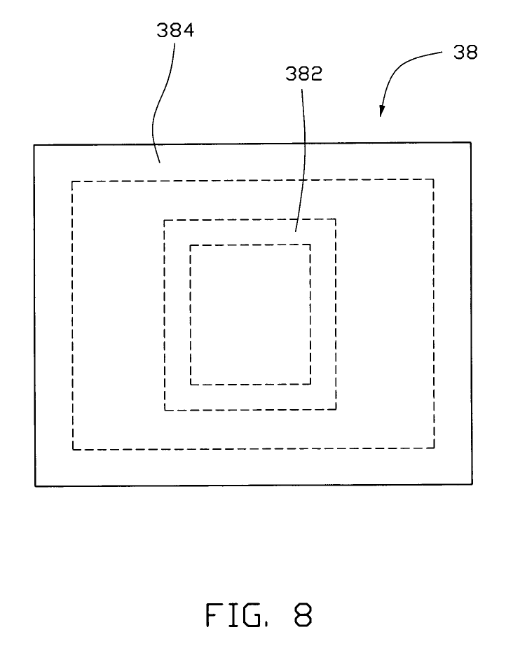

Referring to FIG. 7, the cover 38 is laid over the carrier 32 and the adhesive glue 3262 adheres to the cover 38. Referring to FIG. 8, in this embodiment, the adhesive glue 3262 is adhered to a closed band area 382 of the cover 38. The closed band area 382 is formed in a middle of the cover 38. The closed band area 382 shown herein for illustrative purpose is substantially rectangular band, however, any other shapes such as circular or irregular closed shape may also be used. A brim area 384 of the cover 38 is adhered on the carrier 32 by a bonding glue 386 and therefore seals the image sensor chip 34 in the receiving cavity 321 of the base 324.

The enclosing body 3264 with the cover 38 in the closed band area 382 surrounds a small sealing space 37 configured to seal the photosensitive area 344 therein. It can be seen that the photosensitive area 344 of the image sensor chip 34 is sufficiently protected from outside pollution. Each wire electronically connects the image sensor chip and the carrier. The bonding wires 36 and the connection portion of the bonding wires 36 with the pads are protected by the adhesive glue 3262. Therefore, the characteristics of electronically connection effect may be maintained more stably. In addition, the small sealing space 37 is in the receiving cavity 321. The receiving cavity 321 is sealed by the cover 38, and the photosensitive area 37 is further sealed in the sealing space 37 by the enclosing body 3264. Therefore, the double protection for the photosensitive area 37 effectively prevents water vapor or dust from entering the interior of the package. One main advantage of the digital cameral module with this image sensor chip package is its reliability and high image quality.

In assembly for the image sensor chip package 30 and the lens module, firstly several lens elements 12 are received in the barrel 10. The outer thread 102 of the barrel 10 engages with the inner thread 201 of the seat 20, whereby the barrel 10 and the seat 20 are connected with each other. The seat 20 is then mounted on the image sensor chip package 30 by welding/glue, with the image sensor 34 aligning with the lens elements 12. At the same time, the cover 38 is received in the rectangular cavity 2042. The assembly process of the digital camera module is thus completed.

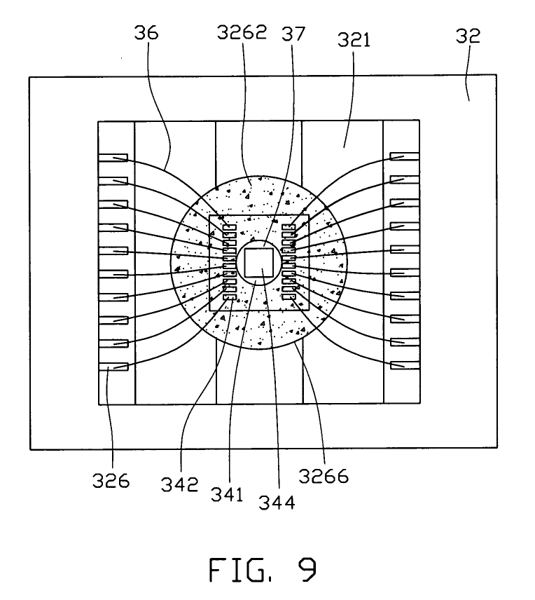

In an alternative embodiment, referring to FIG. 9, the adhesive glue 3262 may only cover one portion of all the bonding wires 36 adjacent to the photosensitive area. The adhesive glue 3262 forms a cylindrical enclosing body 3266. Therefore, the enclosing body 3266 with the cover 38 surrounds the photosensitive area 344 in a small sealing space 37 for protecting the photosensitive area 344. One main advantage of the digital cameral module with this image sensor chip package is its reliability and high image quality. If the principal concern of the image sensor chip package is to protect the photosensitive area 344, then it is generally preferable to only cover a small area around the photosensitive area 344 as will be readily apparent to one skilled in the art of electromagnetic shielding.

In an alternative embodiment, the arrangement of the conductive pieces of the leadframe 320 can be changed so long as the conductive pieces 322 are spaced from each other. The second portion 3222 can be perpendicular to the first and third portions 3220, 3224 rather than being slanted. The base 324 can be of another shape such as cylinder-shaped, or column-shaped with a pentagonal or hexagonal cross-section.

Understandably, the distance between the enclosing body 3264, 3266 and the photosensitive area 344 may be adjusted.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

We claim:

1. An image sensor chip package comprising:
a carrier having a cavity therein;
an image sensor chip received in the cavity, the image sensor having a photosensitive area;
a plurality of wires each electronically connecting the image sensor chip and the carrier;
an adhesive means applied to the image sensor chip around the photosensitive area and covering at least one portion of all the wires adjacent to the photosensitive area, the adhesive means surrounding an enclosing body around the photosensitive area;
a transparent cover mounted to the carrier, the cover adhered to the carrier with the adhesive means, the cover with the enclosing body surrounding a sealing space for enclosing the photosensitive area of the image sensor chip therein.

2. The image sensor chip package as claimed in claim 1, wherein the adhesive means is adhered to a closed band area of the cover, and the band area is defined in a middle of the cover.

3. The image sensor chip package as claimed in claim 2, a brim area of the cover is adhered on the carrier by a bonding glue.

4. The image sensor chip package as claimed in claim 1, wherein the carrier includes a base and a leadframe, the leadframe comprising a plurality of conductive pieces, the conductive pieces of the leadframe being embedded in the base and spaced from each other.

5. The image sensor chip package as claimed in claim 4, wherein the each of the conductive pieces of the leadframe comprises a first portion, a second portion and a third portion, the first and second portions are parallel to and spaced from each other, the second portion is slanted relative to the first and third portions.

6. The image sensor chip package as claimed in claim 1, wherein the adhesive means covering one portion of all the wires adjacent to the photosensitive area, and the adhesive means surrounds a cylindrical enclosing body around the photosensitive area.

7. A digital camera module comprising:
a barrel;
an image sensor chip package, the barrel mounted on the image sensor chip package, the image sensor chip package comprising:
a carrier comprising a conductive means and a base, the conductive means forming a plurality of pads outside the base;
an image sensor chip mounted on the base, the image sensor chip having a top surface, the top surface forming a photosensitive area and a plurality of chip pads around the photosensitive area;
a plurality of wires each respectively electronically connecting a corresponding one of the chip pads of the image sensor chip and the conductive means;
an adhesive means applied on the top surface of the image sensor chip around the photosensitive area of the image sensor chip; and
a transparent cover mounted to the base of the carrier, a closed band area of the cover adhered with the adhesive means, thereby defining a sealing space for sealing the photosensitive area of the image sensor chip therein.

8. The digital camera module as claimed in claim 7, wherein the adhesive means covers all of the wires and the chip pads except the photosensitive area so as to form an enclosing body to surround the photosensitive area.

9. The digital camera module as claimed in claim 7, wherein the base of the carrier has a cavity therein, the conductive means comprises a plurality of conductive pieces embedded in the base and spaced from each other.

10. The digital camera module as claimed in claim 9, wherein each of the conductive pieces of the conductive means comprises a first portion, a second portion and a third portion, the first and third portions are parallel to and spaced from each other, and the second portion is slanted relative to the first and third portions.

11. The digital camera module as claimed in claim 7, further comprising a seat, the seat includes a seat body and a flange, the seat body is connect with the barrel by thread, and the flange is mounted on the image sensor chip package.

12. The digital camera module as claimed in claim 7, wherein the adhesive means is adhered to a closed band area of the cover, and the band area is defined in a middle of the cover.

13. The digital camera module as claimed in claim 12, wherein a brim area of the cover is adhered on the carrier by a bonding glue.

14. A digital camera module comprising:
a barrel;
an image sensor chip package, the barrel mounted on the image sensor chip package, the image sensor chip package comprising:
a carrier including a plurality of conductive means;
an image sensor chip mounted on the carrier, the image sensor chip having a plurality of chip pads and a photosensitive area;
a plurality of wires each respectively electronically connecting a corresponding one of the chip pads of the image sensor chip and the conductive means;
an adhesive means covering an area around the photosensitive area, the adhesive means forming an enclosing body to surround the photosensitive area;
a transparent cover mounted to the base of the carrier, the cover adhered with the adhesive means so as to seal the photosensitive area.

15. The digital camera module as claimed in claim 14, wherein the adhesive means surrounds the wires and the chip pads.

16. The digital camera module as claimed in claim 14, wherein the base of the carrier has a receiving cavity therein, the receiving cavity has a trapezoidal space, and portions of the enclosing body are filled in the trapezoidal space of the receiving cavity.

17. The digital camera module as claimed in claim 14, further comprising a seat, the seat includes a seat body and a flange, the seat body is connect with the barrel by thread, and the flange is mounted on the image sensor chip package.

18. The digital camera module as claimed in claim 14, wherein the adhesive means adheres to a closed band area of the cover.
